(19) United States
(12) Patent Application Publication
(10) Pub. No.: US 2026/0066197 A1
(43) Pub. Date: Mar. 5, 2026

(54) FAST TRIGGER FOR KEYBOARD ANALOG SWITCH

(71) Applicant: Logitech Europe S.A., Lausanne (CH)

(72) Inventors: Feng-Hao Lin, Hsinchu City (TW); Yu-Lun Lin, Miaoli County (TW); Léo Zeender, Lausanne (CH)

(21) Appl. No.: 18/824,764

(22) Filed: Sep. 4, 2024

(51) Int. Cl. H01H 13/52

(52) U.S. Cl. CPC H01H 13/52; H01H 2013/525; H01H 2300/052

(57) ABSTRACT

A sleep mode awakening switch provides a very quick signal to awaken a key's analog sensor from sleep mode with very little movement of the key by a user. This is accomplished using a controlled short distance between a stopper for a spring contact of the switch and a fixed contact of the switch. A protrusion on a key stem lifts the spring contact up to the stopper, with the stopper controlling the travel distance to flip the switch upon a key press.

### BACKGROUND

In some contemporary input devices, such as keyboards, analog keys have become popular for certain applications like competitive gaming. Analog keys can provide better resolution in key press detection that extends beyond a simple make or break connection but can come at a significant increase in production cost, system complexity, and power requirements.

An analog switch has a sensor that can detect the amount of travel of the switch and/or the force applied. Multiple types of sensors can be used, such as magnetic sensing, inductive (e.g., inductive sensor and target with conductive material), capacitive (e.g., electrode sensor and geometric element), optical (e.g., shutter based or reflective), and magnetic (e.g., Hall Effect sensing, and similar sensing methodologies (e.g., TMR, GMR, etc.).

Such analog sensors use power, even when the associated key is not being activated. Accordingly, it is desirable to have a sleep mode to reduce power consumption. With a sleep mode, it is desirable to be able to quickly detect a user touch and wake up the circuitry from the sleep mode to activate the analog sensor and quickly measure the user input.

It should be noted that unless otherwise indicated herein, the materials described in this section are not prior art to the claims in this application and are not admitted to be prior art by inclusion in this section.

### BRIEF SUMMARY

Embodiments provide a keyswitch with a stem movable vertically in response to a user touch. The stem includes a protrusion. An analog sensor circuit is configured to measure an aspect of the movement of the stem. A circuit switch puts the analog sensor circuit into a sleep mode. A first elongated spring contact of the circuit switch is mounted adjacent to the stem with an end extending over the protrusion of the stem such that the end will be lifted when the stem is in an uppermost position (when not being depressed by a user). A first fixed plate contact of the circuit switch is positioned to make an electrical contact with the first elongated spring contact in a vertical position of the stem. A stopper is positioned to limit a vertical movement of the end of the first elongated spring contact such that a circuit signal between the first elongated spring contact and the first fixed plate contact is sent within 0.5 mm of downward vertical movement of the stem from the uppermost position of the stem.

Embodiments thus enable a very quick signal to awaken the key's analog sensor from sleep mode with very little movement of the key by a user. In one embodiment, the circuit signal between the first elongated spring contact and the first fixed plate contact is sent within 0.1 mm of downward vertical movement of the stem from the uppermost position of the stem. Since the analog sensor determines what action is taken, the awakening of the analog sensor with small unintended contact with the key is not an issue, since it can be handled by the processor receiving the analog signal.

In some embodiments, the first fixed plate contact is in contact with the first elongated spring contact when the stem is in the uppermost position. In other embodiments, the first fixed plate contact is in contact with the first elongated spring contact when the stem is depressed.

In one embodiment, the stopper is a first arm of the first fixed plate contact which extends over the protrusion of the stem to limit the amount the protrusion lifts the first elongated spring contact. In one embodiment, a second arm of the first fixed plate contact extends over the protrusion of the stem on an opposite side of the first elongated spring contact from the first arm.

In other embodiments, examples of various modifications are shown. Higher and lower ends of the spring contact are shown. A more compact design uses a single-sided fixed plate stopper. The stopper can be a part of the fixed plate to the side, or higher than the spring contact, or can be on the key housing. Double contact (2 switch) designs are shown with two spring contacts or two fixed contacts.

The terms and expressions that have been employed are used as terms of description and not of limitation, and there is no intention in the use of such terms and expressions of excluding any equivalents of the features shown and described or portions thereof. It is recognized, however, that various modifications are possible within the scope of the systems and methods claimed. Thus, it should be understood that, although the present system and methods have been specifically disclosed by examples and optional features, modification and variation of the concepts herein disclosed should be recognized by those skilled in the art, and that such modifications and variations are considered to be within the scope of the systems and methods as defined by the appended claims.

This summary is not intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim.

The foregoing, together with other features and examples, will be described in more detail below in the following specification, claims, and accompanying drawings.

### BRIEF DESCRIPTION OF THE DRAWINGS

The features of the various embodiments described above, as well as other features and advantages of certain embodiments of the present invention will be more apparent from the following detailed description taken in conjunction with the accompanying drawings, in which:

FIG. 1 is a diagram of a fast trigger design for an analog keyswitch with a double-sided fixed plate stopper, according to an embodiment;

FIG. 2 is a diagram of a contact spring and fixed plate contact of FIG. 1, according to a first embodiment with a higher spring end;

FIG. 3 is a diagram of a contact spring and fixed plate contact of FIG. 1, according to a second embodiment with a lower spring end;

FIG. 4 is a diagram of a fast trigger design for an analog keyswitch with a single-sided fixed plate stopper, according to an embodiment;

FIG. 5 is a diagram of a fast trigger design for an analog keyswitch with a spring contact against a higher fixed plate contact as a stopper, according to an embodiment;

FIG. 6 is a diagram of a side view of the diagram of FIG. 5, according to an embodiment;

FIG. 7 is a diagram of a portion of the fast trigger design with a contact spring engaging riser on the stem protrusion of FIG. 1, according to an embodiment;

FIG. 8 is a diagram of a fast trigger design for an analog keyswitch with two contact springs, according to an embodiment;

FIGS. 9A-B are circuit diagrams of row and column detection circuitry with a sleep mode switch in work and sleep modes, according to an embodiment;

FIG. 10 is a diagram of a fast trigger design for an analog keyswitch with two fixed plate contacts, according to an embodiment.

FIGS. 11-11A are diagrams of a fast trigger design for an analog keyswitch with a long lever arm contact spring, according to an embodiment;

FIG. 12 is a flow chart illustrating a method of operation of a fast trigger for an analog keyswitch, according to an embodiment;

FIG. 13 is a graph illustrating the sleep mode awakening point of the prior art vs. embodiments of the present invention; and

FIGS. 14A-B are diagrams of a design with a base or housing stopper, according to an embodiment; and

FIGS. 15A-B are diagrams of a design with the contacts as a stopper, according to an embodiment.

Throughout the drawings, it should be noted that like reference numbers are typically used to depict the same or similar elements, features, and structures.

### DETAILED DESCRIPTION

Aspects of the present disclosure relate generally to input devices with keys, and more particularly to keys using an analog sensor and having a sleep mode, according to certain embodiments.

In the following description, various examples of mechanical key structures are described. For purposes of explanation, specific configurations and details are set forth in order to provide a thorough understanding of the embodiments. However, it will be apparent to one skilled in the art that certain embodiments may be practiced or implemented without every detail disclosed. Furthermore, well-known features may be omitted or simplified in order to prevent any obfuscation of the novel features described herein.

### Summary

The following high-level summary is intended to provide a basic understanding of some of the novel innovations depicted in the figures and presented in the corresponding descriptions provided below. Aspects of the invention relate to key structures with analog sensors having a trigger switch to wake the analog sensor circuitry from a sleep mode.

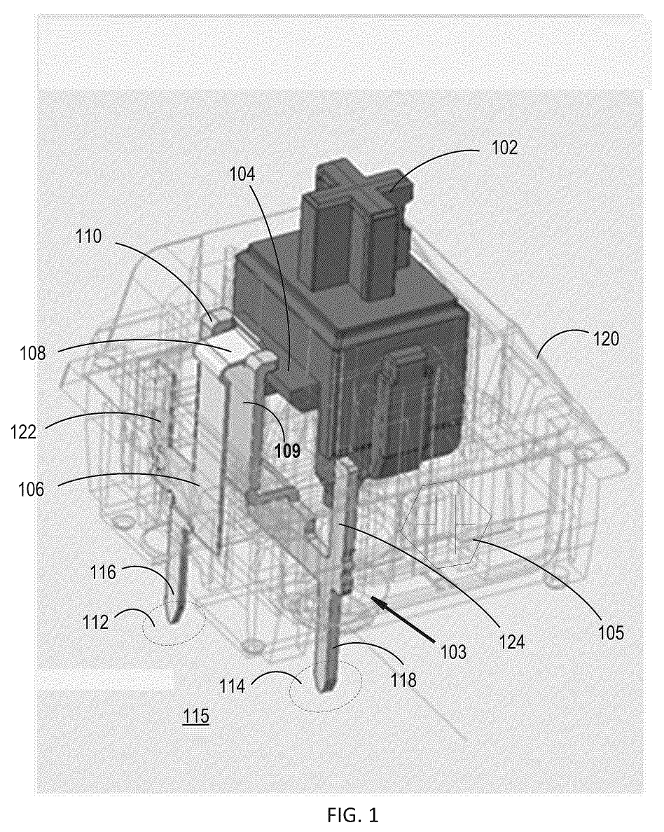

A sleep mode awakening switch provides a very quick signal to awaken a key's analog sensor from sleep mode with very little movement of the key by a user. As illustrated in the embodiment of FIG. 1, this is accomplished using a controlled short distance between a stopper 110 for a spring contact 108 of the switch and a fixed contact 109 of the switch. A protrusion 104 on a key stem 102 lifts the spring contact up to the stopper, with the stopper controlling the travel distance to close the switch upon a key press which depresses key stem 102. In one embodiment, the distance between the stopper and the contact is controlled by a gap on the same fixed plate contact 109, enabling a very tight tolerance by using one element, without adjusting for the positions of different elements.

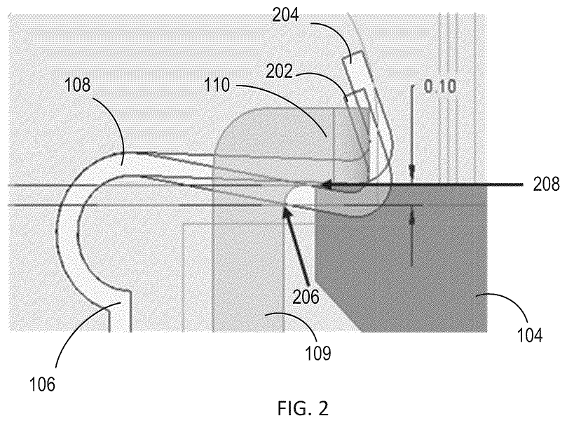

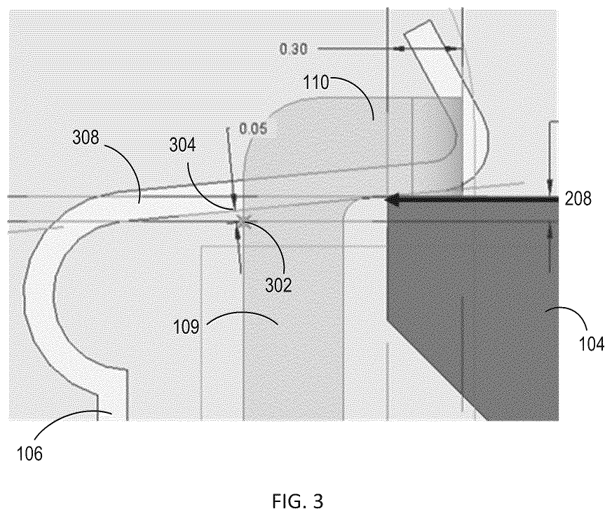

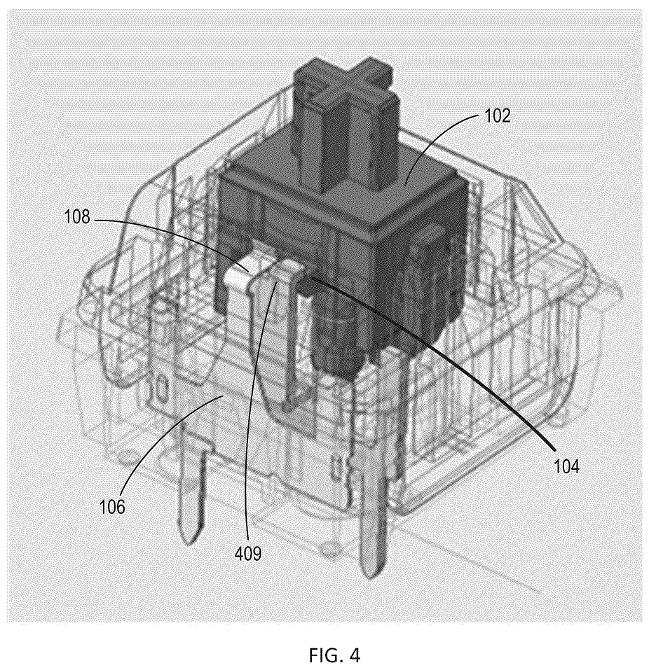

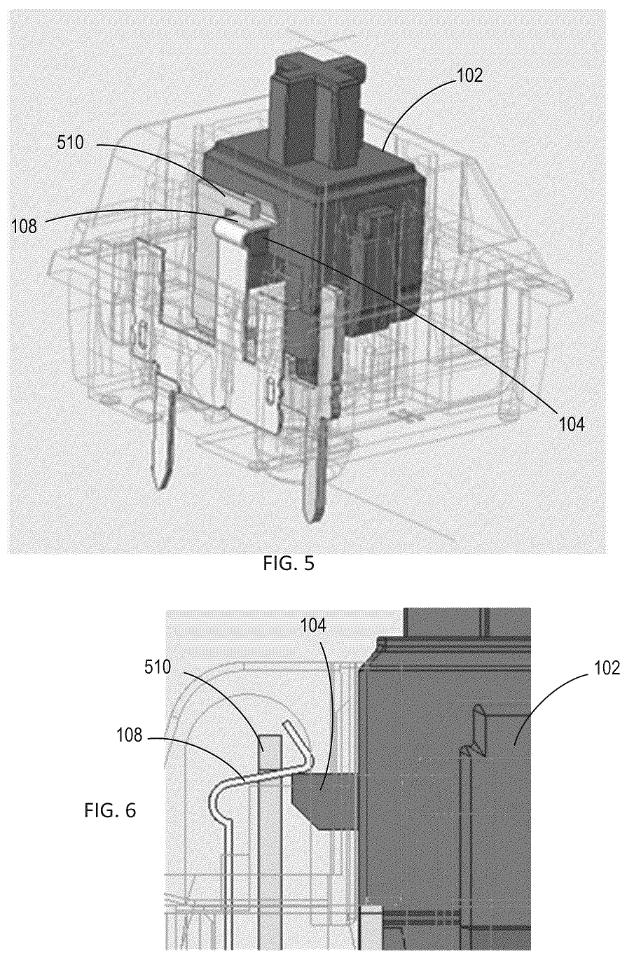

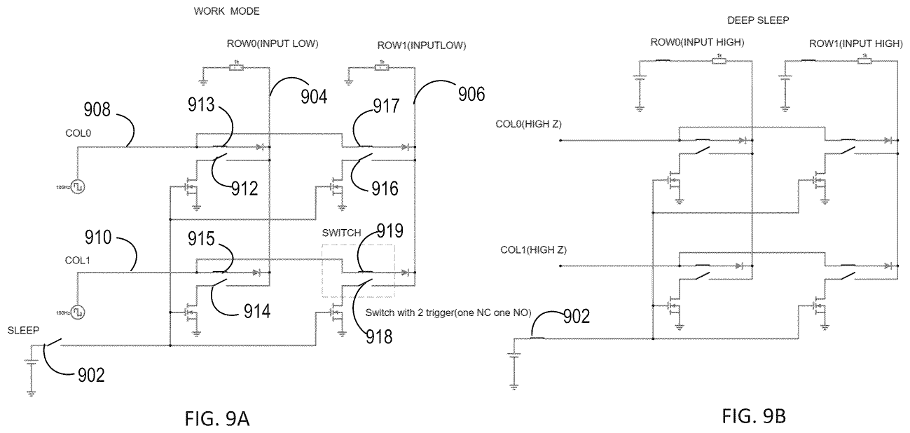

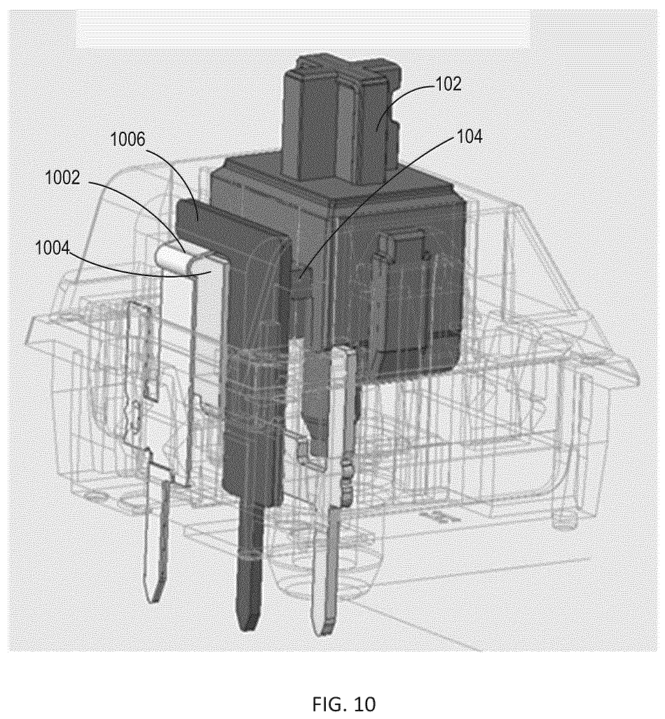

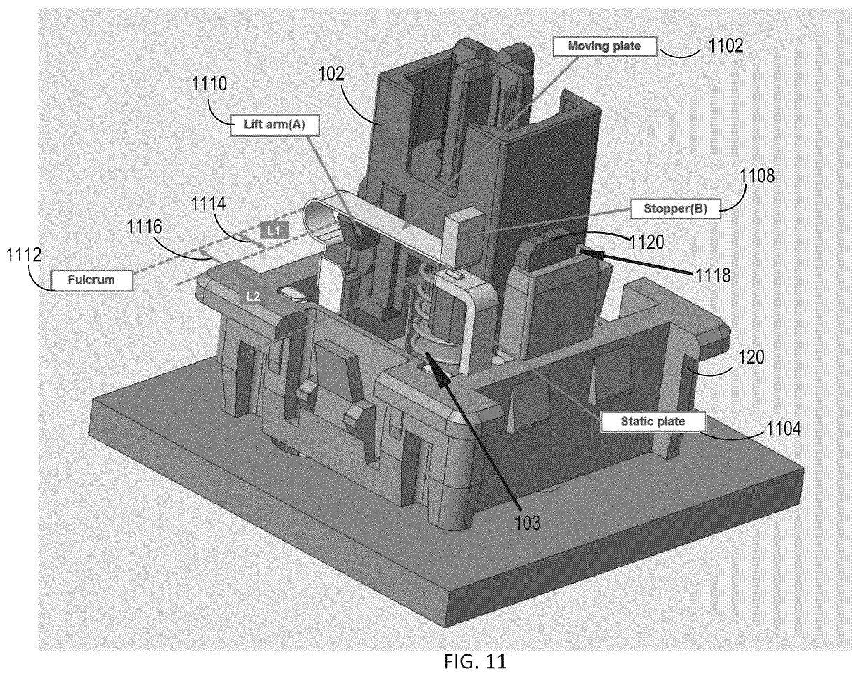

Various modifications are shown in the rest of the figures. FIGS. 2 and 3 show the impact of higher and lower ends of the spring contact. FIG. 4 shows a more compact single-sided fixed plate stopper, contrasting with the double-sided embodiment of FIG. 1. The stopper can be a part of the fixed plate to the side (FIG. 1) or higher (FIGS. 5, 6) than the spring contact, or can be on the key housing (FIG. 11). Examples of double contact (2 switch) designs are shown with two spring contacts (FIG. 9) and two fixed contacts (FIG. 10).

### DETAILED DESCRIPTION

FIG. 1 is a diagram of a fast trigger design for an analog keyswitch, according to an embodiment. A stem 102 is mounted under a keycap, in a base 120 so that the stem can move down in a cavity in the base when depressed by a user. A spring 103 below the stem provides resistance to the user and pushes the stem back upward when the key is released by the user. An analog sensor 105 (not actual shape) measures an aspect of the depression of the key. The aspect measured could be the distance depressed, the amount of force or pressure applied, the acceleration downward, or any other aspect or a combination of aspects. Multiple types of analog sensors can be used, such as magnetic sensing, inductive (e.g., inductive sensor and target with conductive material), capacitive (e.g., electrode sensor and geometric element), optical (e.g., shutter based or reflective), and magnetic (e.g., Hall Effect sensing, and similar sensing methodologies (e.g., TMR, GMR, etc.).

The analog switches and corresponding circuitry need electricity and consume power while waiting for a key depression. Accordingly, in order to conserve battery power for a wireless keyboard, a sleep mode is used. A trigger switch, activated when the user depresses the key, is used. It is desirable to be able to quickly detect a user touch and wake up the circuitry from the sleep mode to activate the analog sensor and quickly measure the user input.

FIG. 1 shows a stem 102 which is movable vertically in response to a user touch, The stem has a stem protrusion 104. A circuit switch for putting the analog sensor into a sleep mode is formed from an elongated spring contact 106 and a fixed plate contact 109. These connect, through pin ends 116 and 118, respectively, to pads 112 and 114, respectively, on a PCB 115. Elongated spring contact 106 is mounted adjacent to the stem 102 with an end 108 of the elongated spring contact extending over the stem protrusion 104 of the stem such that the end will be lifted when the stem is in an uppermost position when not being depressed by a user. The fixed plate contact 109 is positioned to make an electrical contact with the elongated spring contact in a vertical position of the stem. The vertical position can either be the uppermost position, or a slightly lower position. The embodiment of FIG. 1 uses the uppermost position. Arms 110 of fixed plate 109 extend over stem protrusion 104 and act as a stopper positioned to limit a vertical movement of the end of the elongated spring contact (by limiting upward movement of the protrusion, which moves the end 108) such that a circuit signal between the elongated spring contact and the fixed plate contact is sent within 0.3 mm of downward vertical movement of the stem from the uppermost position of the stem. In one embodiment, 0.1 mm or less of movement is sufficient to cause the trigger signal.

As will be explained in more detail with respect to FIGS. 2 and 3 below, fixed plate contact 109 has a contact portion underneath end 108 of spring contact 106. This defines the vertical position where contact is made and the sleep mode switch is closed. Arms 110 on fixed plate contact 109 act as the stop for vertical movement of the stem, and thus as a stop for vertical movement of the end 108 of spring contact 109. Thus, one part, the fixed plate contact 109, defines how far the end 108 needs to travel in order to close the switch and exit sleep mode. This can be controlled to be 0.1 mm or less in embodiments.

In some embodiments, spring contact 106 and fixed plate contact 109 are solid metal pieces. Alternatively, fixed plate contact 109 can be PCB or other material with a metal contact and trace printed on it, or a metal contact and connection imbedded in the material through over molding or another process.

The shapes of spring contact 106 and fixed plate contact 109 are illustrative examples, and other shapes could be used. Spring contact 106 includes an arm 122 that fits into a slot in base 120 and helps position spring contact 106 correctly. Fixed plate contact 109 has a similar arm 124 for the same purpose.

FIG. 2 is a diagram of a contact spring 106 and fixed plate contact 109 of FIG. 1, according to a first embodiment with a higher spring end. End 108 of spring contact 106 is higher than where it contacts fixed plate contact 109 at a point 206 when end 108 is at a lower position 202 as stem protrusion 104 is depressed. When stem 102 is not depressed, it is pushed upward by spring 103 until the stem protrusion 104 is stopped by arms 110 on fixed plate contact 109 at position 204. End 108 is at a point 208 above position 206 in position 204. The difference in height between positions 206 and 208 is 0.10 mm in one embodiment. Thus, the same element, fixed contact plate 109, controls both the high (no contact) and low (contact) positions of end 108 of spring contact 106. By using the same element to control both positions, the distance can be precisely controlled without having to align multiple parts.

FIG. 3 is a diagram of a contact spring 106 and fixed plate contact 109 of FIG. 1, according to a second embodiment with a lower spring end 308. Spring end 308 is lower than a contact point 302 of fixed plate contact 302. Thus, end 308 will contact point 302, on the left in FIG. 3, before contacting the right side of fixed plate contact 109. Stem protrusion 104 will lift end 308 off of fixed plate contact 109 to a position 304 when stem protrusion 104 contacts arms 110 on fixed plate contact 109 at position 208. As in FIG. 2, the distance between the contact point 302 and position 208 is a vertical 0.10 mm. However, since spring end 308 is lower, and contacts the left side of fixed plate contact 109 first, it stops at a position 304 which is only 0.050 mm above contact point 302. By having spring end 308 lower, it takes advantage of a lever arm effect. The spring end 308 angles downward from position 208 to contact point 302, thus creating an even smaller distance between the rest position and the contact position of spring contact 106 at the beginning of the depression of a button by the user. Since the stem still needs to travel 0.10 mm downward, the embodiment of FIG. 2 has the advantage of a looser tolerance between the spring contact and the fixed plate contact.

FIG. 4 is a diagram of a fast trigger design for an analog keyswitch with a single arm fixed plate stopper 409, according to an embodiment. Given the limited space in the key housing, the fixed plate can be optimized with various shapes while maintaining the same principle. The single arm example of FIG. 4 is one possible design that will take up less room by using a single arm instead of two arms. Arm 409 is only on one side of spring end 108, instead of both sides as in FIGS. 1-3. Otherwise, the design of FIG. 4 operates similarly to the embodiments shown in FIGS. 1-3.

FIG. 5 is a diagram of a fast trigger design for an analog keyswitch with a spring contact against a higher fixed plate contact arm 510 as a stopper, according to an embodiment. In this embodiment, stem protrusion 104 pushes spring contact end 108 into the bottom of fixed plate contact 510, which is over the spring contact end 108. Fixed plate contact arm 510 acts as a stopper arm, but with spring end 108 between it and the stem protrusion 104. Fixed plate contact arm 510 also acts as the contact, with contact on the arm closing the switch, as opposed to the earlier figures where the contact is between the arms, or to the side of an arm. In this design, the sleep mode switch is closed by the contact between spring end 108 and fixed plate contact arm 510. When stem 102 is pushed downward by a user pressing the button, spring end 108 is almost instantly released from fixed plate contact 510, opening the switch and waking the circuit from sleep mode.

FIG. 6 is a diagram of a side view of the diagram of FIG. 5, according to an embodiment. As can be seen, stem protrusion 104 pushes spring contact end 108 into the bottom of fixed plate contact arm 510, which is over the spring contact end 108. Fixed plate contact arm 510 acts as a stopper arm, but with spring end 108 between it and the stem protrusion 104. When stem 102 is pushed downward by a user pressing the button, spring end 108 is almost instantly released from fixed plate contact 510, opening the switch and waking the circuit from sleep mode.

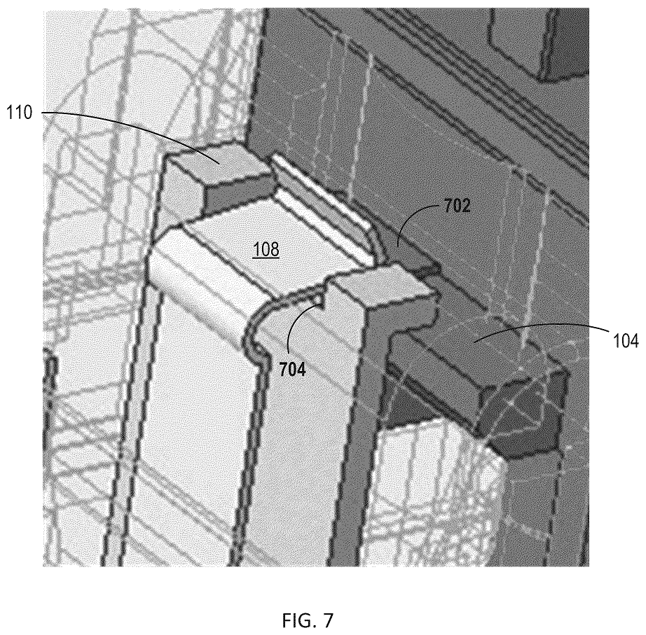

FIG. 7 is a diagram of a portion of the fast trigger design with a contact spring engaging riser on the stem protrusion of FIG. 1, according to an embodiment. As in previous embodiments, arms 110 of the fixed contact plate act as a stop for the stem by engaging a protrusion 104. In this embodiment, a riser 702 is added to protrusion 104 to cause end 108 of the contact spring to lift up more. This could be useful if the gap between arms 110 and where end 108 contacts the fixed plate isn't well controlled. Riser 702 ensures that the end 108 of the contact spring is lifted, opening the sleep mode switch. Alternately, this allows the contact portion 704 of the fixed plate to be at the same vertical level as the bottom of arms 110.

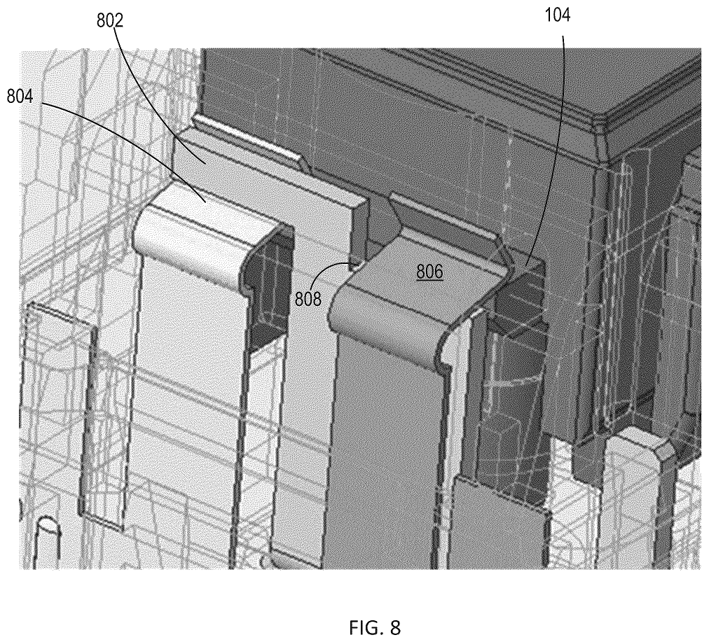

FIG. 8 is a diagram of a fast trigger design for an analog keyswitch with two contact springs, according to an embodiment. This embodiment uses two moving plates, spring contacts 804 and 806. In FIG. 8, in the rest position (without a user pressing), spring contact 804 is in contact with fixed plate contact 802, providing a closed switch. At the same time, spring contact 806 is lifted off fixed plate contact 808, providing an open switch. Both use the same fixed plate 802 to complete the switch. The same stem protrusion 104 lifts both spring contacts 804 and 806. Spring contact 804 is pushed upward against fixed plate contact arm 802, which acts as both a contact and a stopper, similar to the embodiment of FIG. 5. This allows a greater variety of sleep mode circuit designs. For example, spring contact 806 can provide a sleep wake-up signal for the entire keyboard. It is open when not pressed, and thus has a gap, which means the keyboard cannot be turned on immediately. But once turned on, with the keyboard exiting sleep mode and entering a work mode, spring contact 804 and fixed contact 802 form a separate switch for each key to turn on the analog sensor for just that key. This is only detected after the keyboard has exited sleep mode. Thus, during operation, the analog sensor for each key can be turned on instantly, since there is no gap between spring contract 804 and fixed contact 802 when not pressed.

FIGS. 9A-B are circuit diagrams of row and column detection circuitry with a sleep mode switch in work and sleep modes, according to an embodiment. FIG. 9A shows a work mode where sleep mode switch 902 in an open state. FIG. 9B shows a sleep mode where sleep mode switch 902 is closed. In the sleep mode, the matrix is not scanned, saving power. In the work mode the keyboard will scan the matrix and detect whether any of the keyswitches are closed. If there are no key presses for a determined period of time, the firmware determines that there is no typing and the system enters a sleep mode by closing switch 902. The circuit shows the switch matrix for four different keys, which are at the intersections of row 904 (row 0), row 906 (row 1), column 908 (col. 0) and column 910 (col. 1). The particular key is indicated by connecting the corresponding row and column. The key at ROW 1, COL 0 has two connected switches, 916 (808+806 of FIG. 8, normally open without a key press) and 917 (802+804 of FIG. 8, normally closed). The two switches are part of the same key as shown in FIG. 8. The keyboard work mode and sleep mode are controlled by switch 916. The analog sensor on/off for the key is controlled by switch 917. By pressing the key and closing switch 916, switch 702 will be opened from the closed sleep mode in FIG. 9B to the open work mode shown in FIG. 9A. Then in work mode, the keyboard will thereafter detect the opening of switch 917 to control the on/off of the analog sensor for that key. Because switch 917 (802+804 of FIG. 8) is normally closed without a gap, the sensor can be tuned on instantly. The other keys work in the same manner. Any one of switches 912, 914, 916 or 918 closing will awaken the keyboard and thereafter the opening of switches 913, 915, 917 or 919 will indicate a key press for the corresponding key and turn on the analog sensor for that key.

By turning off the analog sensor or making the keyboard sleep, power consumption is reduced without affecting the use of the keyboard. While in sleep mode, the keyboard does not need to scan the matrix of keys but will detect whether any of switches 912, 914, 916 and 918 is closed to wake up the system on the keyboard. The matrix does not need to be scanned to determine that one of those keyswitches has closed—at that point, it is not important to determine which key is pressed, just that a key has been pressed. After the keyboard is awakened from sleep mode and is in work mode, the matrix will be scanned to detect which of switches 913, 915, 917 or 919 is opened. But power is also saved during work mode, since the corresponding analog sensor for those switches is not turned on until the corresponding switch of switches 913, 915, 917 or 919 is opened. Alternate embodiments can use different circuitry. For example, the circuitry could be designed so that the sleep mode is entered when the sleep mode switch is open, and exited when the sleep mode switch is closed.

FIG. 10 is a diagram of a fast trigger design for an analog keyswitch with two fixed plate contacts, according to an embodiment. In the rest position, without a user pressing a key, spring contact end 1002 is pushed up against fixed plate contact 1006 by protrusion 104. Fixed plate contact 1006 acts as a stopper, with spring contact end 1002 being pushed up against it. When a user depresses stem 102, spring contact end 1002 comes into contact with the top of fixed plate contact 1004. Thus, in a sleep mode, the switch of contacts 1002 and 1006 is closed, while the switch of contacts 1002 and 1004 is open. The switches are in the opposite states when a user depresses the key, with switch 1002/1006 opening and switch 1002/1004 closing. The two switches operate similarly to the two switches of FIG. 9, as described above, except that the switches are now formed with a common spring contact and two fixed plate contacts. In this design, the closing of the switch of spring contact end 1002 and fixed plate contact 1004 awakens the keyboard from sleep mode after a key press traverses the gap between the two fixed plates. Thereafter, during work mode when the keyboard is awake, the opening of the switch formed by spring contact end 1002 and fixed plate contact 1006, which happens instantly upon a press, turns on the analog sensor for that key.

FIG. 11 is a diagram of a fast trigger design for an analog keyswitch with a long lever arm contact spring, according to an embodiment. In this design, the spring contact is a long moving plate 1102. It can be made longer than the designs discussed above because it runs adjacent and parallel to a wall of the stem 102, instead of running toward the stem. Moving plate 1102 is a spring biased downward to be in contact with a fixed plate contact, static plate 1104. In the embodiment shown, a stopper 1108 is formed as part of the key housing, to keep moving plate 1102 from rising more than 0.10 mm above static plate 1104. Alternately, static plate 1104 could have an arm above moving plate 1102 to act as a stopper, with a non-conductive surface where it comes in contact with moving plate 1102.

A lift arm 1110 lifts moving plate 1102 upward, until the far end is stopped by stopper 1108. The moving plate has a fulcrum 1112, providing a lever arm effect, so that a point 1114 (L1) of the moving plate bends less than a portion 1116 (L2) of the moving plate. Thus, a smaller movement downward of the stem 102 causes a small motion downward at L1, while causing a greater movement downward at L2. Thus, the gap at L2 can be, for example, 0.10 mm, with the gap at L1 being smaller. Thus, a smaller movement than the possible design tolerance at L2 can wake the circuit from the sleep mode.

The lift arm 1110 on the stem 102 will lift the moving plate 1102 to disconnect it from plate 1104, thus putting the analog switch circuit into sleep mode. Due to the lever effect, the lift distance at lift arm 1110 (A in the equation below) is less than the lift distance at stopper 1108 (B in the equation below). Thus the lift distance at A*L2=the lift distance at the stopper (B)*L1. This means that if the gap at (B) point is 0.1 mm, the gap at (A) is 0.1 mm*L1/L2 which will be smaller than 0.1 mm. Thus, a faster trigger is provided. FIG. 11 also shows a guide slot 1118 in base 120 that guides an extension 1120 of stem 102 as it moves up and down against spring 103.

FIG. 11A is a view from below of the structure of FIG. 11, showing an end of moving plate 1102 stopped by stopper 1108 and disconnected from fixed plate 1104. Also visible in the view are the ends of moving plate 1102 and fixed plate 1104 extending into contact holes of PCB 115.

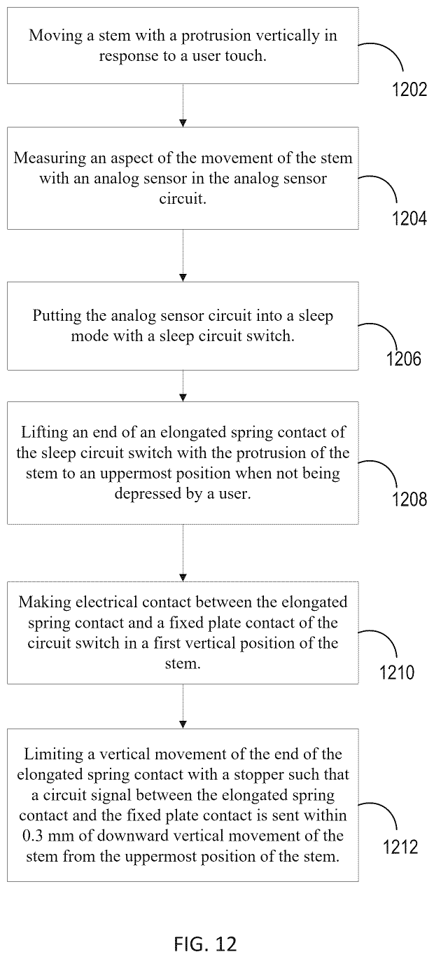

FIG. 12 is a flow chart illustrating a method of operation of a fast trigger for an analog keyswitch, according to an embodiment. The method provides a trigger signal upon depression of a keyswitch to exit a sleep mode for an analog circuit. Step 1202 is moving a stem with a protrusion vertically in response to a user touch. Step 1204 is measuring an aspect of the movement of the stem with an analog sensor in the analog sensor circuit. Step 1206 is putting the analog sensor circuit into a sleep mode with a sleep circuit switch. Step 1208 is lifting an end of an elongated spring contact of the sleep circuit switch with the protrusion of the stem to an uppermost position when not being depressed by a user. Step 1210 is making electrical contact between the elongated spring contact and a fixed plate contact of the circuit switch in a first vertical position of the stem. Step 1212 is limiting a vertical movement of the end of the elongated spring contact with a stopper such that a circuit signal between the elongated spring contact and the fixed plate contact is sent within 0.3 mm of downward vertical movement of the stem from the uppermost position of the stem. In one embodiment, the circuit signal is sent within 0.10 mm or less of downward vertical movement.

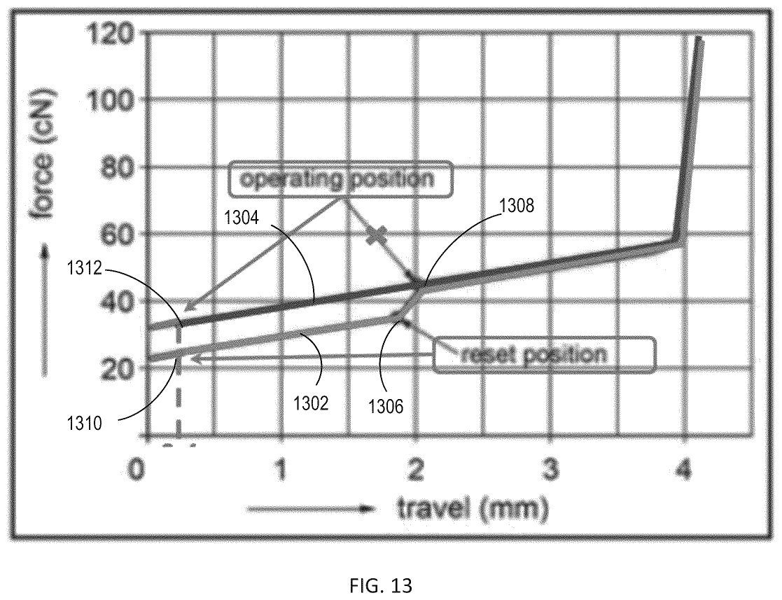

FIG. 13 is a graph illustrating the sleep mode awakening point of the prior art vs. embodiments of the present invention. Upper line 1304 is the force profile of pressing. After pressing, line 1302 is the force profile of releasing. A typical linear mechanical switch of the prior art allows 2 mm of travel before a galvanic trigger awakens the circuit from sleep mode at a point 1306, to awaken (reset) the analog sensor. After a slight delay, the analog sensor begins operating at a point 1308, giving an operating range starting at point 1308 and extending to the right in the graph. Embodiments of the present invention provide a trigger at 0.10 mm at a point 1310, giving an operating range starting much earlier, at a point 1312. The analog sensor turns on when the contact signal from 1312 is received. For comparison and reference, 1308 and 1306 are the travels of traditional galvanic switches with on (2 mm) and off (1.8 mm).

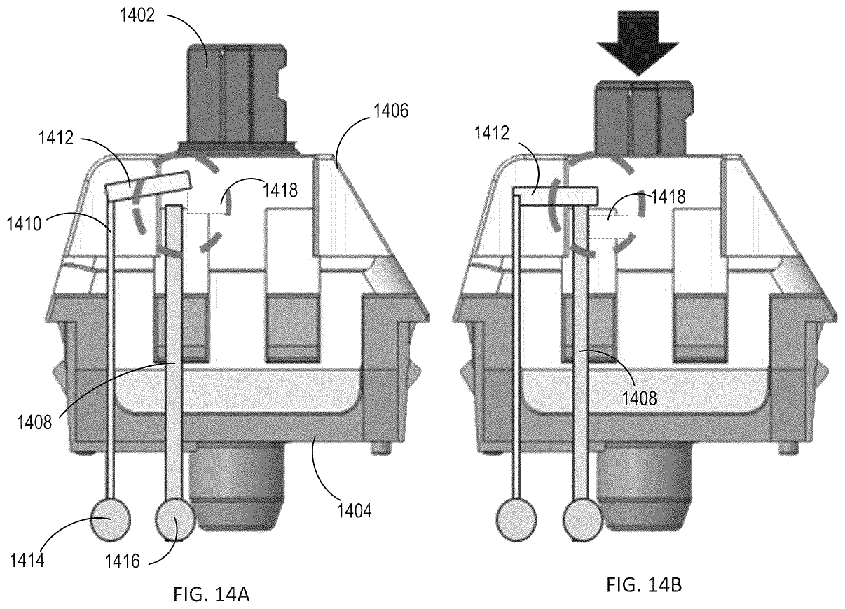

FIGS. 14A-B are diagrams of a design with a base or housing stopper, according to an embodiment. A stem 1402 is mounted in a base 1404 which is mounted in a key housing 1406. A fixed plate contact 1408 and a spring contact 1410 are provided. The spring contact has an end 1412. Spring contact 1410 connects to a PCB pad 1414 and fixed contact 1408 connects to a PCB pad 1416. End 1412 of spring contact 1410 is lifted off fixed contact 1408 by a protrusion 1418 on stem 1402. The stopper is the upper portion of the housing which stops the upward movement of the stem, thereby stopping the upward movement of end 1412. As shown in FIG. 14B, when the stem is depressed, protrusion 1418 descends, allowed the spring bias of spring contact 1410 to bring spring end 1412 into contact with fixed contact 1408, closing the sleep awakening switch.

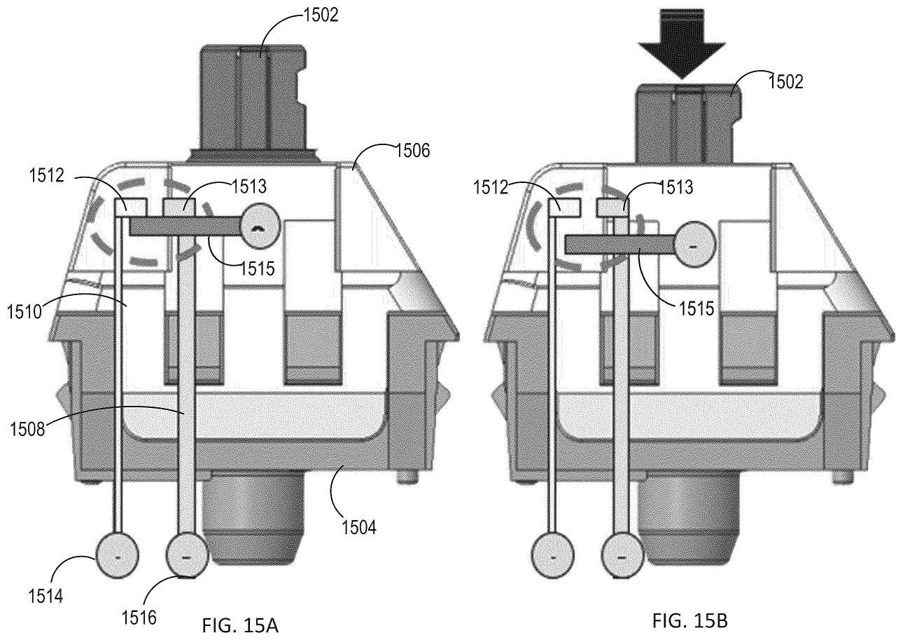

FIGS. 15A-B are diagrams of a design with the contacts as a stopper, according to an embodiment. A stem 1502 is mounted in a base 1504 which is mounted in a key housing 1506. A fixed plate contact 1508 and a spring contact 1510 are provided. The spring contact has an end 1512 and the fixed contact has an end 1513. Spring contact 1510 connects to a PCB pad 1514 and fixed contact 1508 connects to a PCB pad 1516. A bridge contact 1515 connects to the stem 1502. When the stem is in the up position, the bridge contact 1515 connects ends 1512 and 1513, closing the sleep mode switch. Ends 1512 and 1513 can both be spring loaded, or can both be fixed, or one can be spring loaded and the other could be fixed. As soon as the stem is depressed, as shown in FIG. 15B, bridge contact 1515 separates from the ends 1512 and 1513, causing the switch to open. For this design, the sleep circuit is configured to awaken when the sleep switch is opened. In the embodiment of FIGS. 15A-B, the sleep switch is normally closed (connected). As soon as the key is pressed, the pins will disconnect and the analog sensor will turn on.

### Alternate Embodiments

The specific embodiments described herein can be varied while still being within the scope of the invention as set forth in the claims below. For example, two lever arms of FIG. 11 could be used, on orthogonal sides of the key stem, to give a two-switch solution. The stopper could be on the base which supports the key stem, rather than on the key stem or the key housing. A stopper on the base or housing could be used instead of a stopper on the stem in any of the embodiments showing the stopper on the stem. Stoppers can also be designed on static plates (1104) or any other cases. Since the stem is a moving part, there is no stopper on it. In different embodiments, the stopper is positioned to limit a vertical movement of the end of the first elongated spring contact such that a circuit signal between the first elongated spring contact and the first fixed plate contact is sent within 0.5 mm, 0.3 mm, 0.2 mm, 0.1 mm or less.

Numerous specific details are set forth herein to provide a thorough understanding of the claimed subject matter. However, those skilled in the art will understand that the claimed subject matter may be practiced without these specific details. In other instances, methods, apparatuses, or systems that would be known by one of ordinary skill have not been described in detail so as not to obscure claimed subject matter. The various embodiments illustrated and described are provided merely as examples to illustrate various features of the claims. However, features shown and described with respect to any given embodiment are not necessarily limited to the associated embodiment and may be used or combined with other embodiments that are shown and described. Further, the claims are not intended to be limited by any one example embodiment.

While the present subject matter has been described in detail with respect to specific embodiments thereof, it will be appreciated that those skilled in the art, upon attaining an understanding of the foregoing may readily produce alterations to, variations of, and equivalents to such embodiments. Accordingly, it should be understood that the present disclosure has been presented for purposes of example rather than limitation, and does not preclude inclusion of such modifications, variations, and/or additions to the present subject matter as would be readily apparent to one of ordinary skill in the art. Indeed, the methods and systems described herein may be embodied in a variety of other forms; furthermore, various omissions, substitutions and changes in the form of the methods and systems described herein may be made without departing from the spirit of the present disclosure. The accompanying claims and their equivalents are intended to cover such forms or modifications as would fall within the scope and spirit of the present disclosure.

Although the present disclosure provides certain example embodiments and applications, other embodiments that are apparent to those of ordinary skill in the art, including embodiments which do not provide all of the features and advantages set forth herein, are also within the scope of this disclosure. Accordingly, the scope of the present disclosure is intended to be defined only by reference to the appended claims.

Conditional language used herein, such as, among others, “can,” “could,” “might,” “may,” “e.g.,” and the like, unless specifically stated otherwise, or otherwise understood within the context as used, is generally intended to convey that certain examples include, while other examples do not include, certain features, elements, and/or steps. Thus, such conditional language is not generally intended to imply that features, elements and/or steps are in any way required for one or more examples or that one or more examples necessarily include logic for deciding, with or without author input or prompting, whether these features, elements and/or steps are included or are to be performed in any particular example.

The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Similarly, the use of “based at least in part on” is meant to be open and inclusive, in that a process, step, calculation, or other action “based at least in part on” one or more recited conditions or values may, in practice, be based on additional conditions or values beyond those recited. Headings, lists, and numbering included herein are for ease of explanation only and are not meant to be limiting.

What is claimed is:

1. A keyswitch comprising:
a stem movable vertically in response to a user touch and having a protrusion;
an analog sensor circuit configured to measure an aspect of the movement of the stem;
a circuit switch for putting the analog sensor circuit into a sleep mode;
a first elongated spring contact of the circuit switch mounted adjacent to the stem with an end of the first elongated spring contact extending over the protrusion of the stem such that the end will be lifted when the stem is in an uppermost position when not being depressed by a user;
a first fixed plate contact of the circuit switch positioned to make an electrical contact with the first elongated spring contact in a vertical position of the stem; and
a stopper positioned to limit a vertical movement of the end of the first elongated spring contact such that a circuit signal between the first elongated spring contact and the first fixed plate contact is sent within 0.5 mm of downward vertical movement of the stem from the uppermost position of the stem.

2. The keyswitch of claim 1 wherein the first fixed plate contact is in contact with the first elongated spring contact when the stem is in the uppermost position.

3. The keyswitch of claim 1 wherein the first fixed plate contact is in contact with the first elongated spring contact when the stem is depressed.

4. The keyswitch of claim 1 wherein the stopper is a first arm of the first fixed plate contact which extends over the protrusion of the stem to limit the amount the protrusion lifts the first elongated spring contact.

5. The keyswitch of claim 4 further comprising a second arm of the first fixed plate contact which extends over the protrusion of the stem on an opposite side of the first elongated spring contact from the first arm.

6. The keyswitch of claim 1 wherein the circuit signal between the first elongated spring contact and the first fixed plate contact is sent within 0.1 mm of downward vertical movement of the stem from the uppermost position of the stem.

7. The keyswitch of claim 1 wherein the first elongated spring contact comprises a vertical portion, a curved portion connected to the vertical portion and extending above a contact portion of the first fixed plate contact, and an arm extending from the curved portion to a position above the contact portion of the first fixed plate contact, the arm being spring-biased to press downward against the contact portion of the first fixed plate contact.

8. The keyswitch of claim 1 wherein the stopper is a first arm of the first fixed plate contact which extends over the first elongated spring contact.

9. The keyswitch of claim 8 further comprising a second elongated spring contact adjacent the first elongated spring contact and extending over the first fixed plate contact and the protrusion of the stem, the second elongated spring contact being part of a second switch with the first fixed plate contact and being in an open position when the first elongated spring contact is in a closed position, wherein the second switch awakens a keyboard circuit from a sleep mode and the first switch turns on the analog sensor when the keyboard is awake.

10. The keyswitch of claim 8 further comprising a second fixed plate contact below the first elongated spring contact and being part of a second switch with the first elongated spring contact and being in an open position when the first fixed plate contact is in a closed position, wherein the first switch awakens a keyboard circuit from a sleep mode and the second switch turns on the analog sensor when the keyboard is awake.

11. The keyswitch of claim 1 wherein the stopper is a part of a key housing.

12. The keyswitch of claim 1 wherein the first elongated spring contact has a vertical portion and a horizontal portion, with the horizontal portion extending adjacent and parallel to one side of the stem over the protrusion of the stem proximate the vertical portion with a distal end of the horizontal portion being over the first fixed plate contact; and
wherein the stopper is over the distal end of the horizontal portion of the first spring contact.

13. The keyswitch of claim 1 wherein the stopper comprises an electrically conductive contact connecting the first elongated spring contact and the fixed plate contact.

14. A keyswitch comprising:
a stem movable vertically in response to a user touch and having a protrusion;
an analog sensor circuit configured to measure an aspect of a movement of the stem;
a circuit switch for putting the analog sensor circuit into a sleep mode;
a first elongated spring contact of the circuit switch mounted adjacent to the stem with a portion of the first elongated spring contact extending over the protrusion of the stem such that the first elongated spring contact will be lifted when the stem is in an uppermost position when not being depressed by a user;
a first fixed plate contact of the circuit switch positioned to make an electrical contact with the first elongated spring contact in a vertical position of the stem;
a stopper positioned to limit a vertical movement of the first elongated spring contact such that a circuit signal between the first elongated spring contact and the first fixed plate contact is sent within 0.2 mm of downward vertical movement of the stem from the uppermost position of the stem, wherein the stopper is a first arm of the first fixed plate contact which extends over the protrusion of the stem to limit an amount the protrusion lifts the first elongated spring contact; and
wherein the first fixed plate contact is in contact with the first elongated spring contact when the stem is depressed.

15. The keyswitch of claim 14 further comprising a second arm of the first fixed plate contact which extends over the protrusion of the stem on an opposite side of the first elongated spring contact from the first arm.

16. The keyswitch of claim 14 wherein the circuit signal between the first elongated spring contact and the first fixed plate contact is sent within 0.1 mm of downward vertical movement of the stem from the uppermost position of the stem.

17. The keyswitch of claim 14 wherein the first elongated spring contact comprises a vertical portion, a curved portion connected to the vertical portion and extending above a contact portion of the first fixed plate contact, and an arm extending from the curved portion to a position above the contact portion of the first fixed plate contact, the arm being spring-biased to press downward against the contact portion of the first fixed plate contact.

18. The keyswitch of claim 14 wherein the first elongated spring contact has a vertical portion and a horizontal portion, with the horizontal portion extending adjacent and parallel to one side of the stem over the protrusion of the stem proximate the vertical portion with a distal end of the horizontal portion being over the first fixed plate contact; and
wherein the stopper is over the distal end of the horizontal portion of the first spring contact.

19. A method for providing a trigger signal upon depression of a keyswitch to exit a sleep mode for an analog sensor circuit comprising:
moving a stem vertically in response to a user touch, the stem including a protrusion;
measuring an aspect of the movement of the stem with an analog sensor in the analog sensor circuit;
putting the analog sensor circuit into a sleep mode with a sleep circuit switch;
lifting an end of an elongated spring contact of the sleep circuit switch with the protrusion of the stem to an uppermost position when not being depressed by a user;
making electrical contact between the elongated spring contact and a fixed plate contact of the circuit switch in a first vertical position of the stem; and
limiting a vertical movement of the end of the elongated spring contact with a stopper such that a circuit signal between the elongated spring contact and the fixed plate contact is sent within 0.3 mm of downward vertical movement of the stem from the uppermost position of the stem.

20. The method of claim 19 wherein the fixed plate contact is in contact with the elongated spring contact when the stem is depressed.
